(19) United States
(12) Patent Application Publication
(10) Pub. No.: US 2007/0242550 A1
(43) Pub. Date: Oct. 18, 2007

(54) Device and method of controlling operation of a flash memory

(75) Inventors: Menahem Lasser, Kohav Yair (IL); Aviram Hadash, Modiin (IL)

Correspondence Address: MARK M. FRIEDMAN, C/O DISCOVEY DISPATCH , 9003 FLIRIN WAY, UPPER MARLBORO, MD, 20772, US

(73) Assignee: SanDisk IL LTD.

(21) Appl. No.: 11/655,865

(22) Filed: Jan. 22, 2007

Related U.S. Application Data
(60) Provisional application No. 60/743,887, filed on Mar. 29, 2006.

(51) Int. Cl. G11C 5/14

(52) U.S. Cl. 365/226

(57) ABSTRACT

A flash memory device including a non-volatile memory for storing information; a power switch for controlling operation of the non-volatile memory; and a controller that operates the power switch to alternately provide and deny power to the non-volatile memory.

### CROSS-REFERENCE TO RELATED APPLICATIONS

This patent application claims the benefit of U.S. Provisional Patent Application No. 60/743,887 filed Mar. 29, 2006.

### FIELD OF THE INVENTION

The present invention relates to storage devices. More particularly, the present invention relates to a device and method of controlling operation of a flash memory.

### BACKGROUND OF THE INVENTION

Portable computing devices that operate on batteries are well known in the art. One of the main design considerations in such devices is preservation of battery power. Therefore, the operating systems of such devices typically turn off the power to peripherals when the peripherals are not being used.

Some peripherals need a setup time when turned on. If such peripherals are turned off for power conservation, the user may experience a long delay when the peripherals are turned on. Such peripherals typically have a “power preservation mode” in which the peripherals are disabled from operation but are kept ready for use when needed. Such modes of operation are typically called “stand by” or “hibernate”.

Flash memory devices, such as DiskOnChip®, available from systems, Kfar Sava, Israel, include two sub-units—a controller die or Integrated Circuit (IC) and a flash memory die or IC. These two sub-units differ from one another in two major aspects. In comparison to the flash memory, the controller consumes less current when operating. However, in comparison to the flash memory, the controller requires a longer warm-up time to resume operation when turned on. For the purpose of the present invention the term “flash memory” refers to the non-volatile flash memory media without the memory's controller, why the term “flash memory device” refers to the combination of the non-volatile flash memory media with the memory's controller.

According to existing techniques, power is either enabled to all sub-units of the flash memory device or disabled to all sub-units of the flash memory device. As such, it is not possible to enable power to only some components of the flash memory device while at the same time preventing power to other components.

Thus, it would be desirable to configure flash memory devices to maintain power to only some components, thereby providing optimal power saving.

### SUMMARY OF THE INVENTION

Accordingly, it is a principal object of the present invention to introduce a flash memory device to maintain power to only some components of the flash memory device such as a controller, while completely turning off other components such as flash memory components, thereby providing optimal power saving.

The flash controller of the flash memory device is configured to control power supply to the flash memory of the flash memory device, thereby alternately providing and denying power to the flash memory.

In contrast to prior art techniques, in which the flash memory is powered directly from the external power source and is always powered when the controller is powered, the flash memory of the present invention is disconnected from power when not in use by the host for a preset time interval, or following an explicit command to that effect sent by the host. When the host requests access to the flash memory following such disconnection, the flash controller of the present invention provides power to the flash memory and resumes its operation. Such configuration provides optimal power saving.

In accordance with a preferred embodiment, there is provided a flash memory device that includes: (a) a non-volatile memory for storing information; (b) a power switch for controlling operation of the memory device; and (c) a controller that operates the power switch to alternately provide and deny power to the non-volatile memory.

Preferably, the power switch is implemented within the controller. Alternatively, the power switch is external to the controller.

Preferably, the controller is operative to alternately provide and deny power to the non-volatile memory in response to commands received from a host.

Preferably, the controller is operative to alternately provide and deny power to the non-volatile memory contingent on a value of the time it takes to activate the non-volatile memory. Alternatively or additionally, the controller is operative to alternately provide and deny power to the non-volatile memory contingent on a value of the history of use of the non-volatile memory. By “history of use” it is referred here to any information regarding previous use of the non-volatile memory. An example for this can be the average time between successive accesses by the host to the non-volatile memory as measured by the controller over a predetermined time interval, where the controller may deny power from the memory if based on this average the next host access is expected far enough from the present time.

In accordance with another embodiment, there is further provided a method of regulating power consumption of a flash memory device that includes a nonvolatile memory and a controller of the nonvolatile memory, the method includes the steps of: (a) supplying power to the controller; and (b) alternately providing and denying the supply of power, by the controller, to the non-volatile memory.

Preferably, the alternately providing and denying supply of power to the non-volatile memory is effected in response to commands received from a host of the memory device.

Preferably, the alternately providing and denying supply of power to the non-volatile memory is contingent on a value of time required to activate the non-volatile memory. Alternatively or additionally, the controller is operative to alternately provide and deny power to the non-volatile memory contingent on a value of history of use of the non-volatile memory.

Additional features and advantages of the invention will become apparent from the following drawings and description.

### BRIEF DESCRIPTION OF THE DRAWINGS

For a better understanding of the invention with regard to the embodiments thereof, reference is made to the accompanying drawings, in which like numerals designate corresponding sections or elements throughout, and in which:

FIG. 1 is a block diagram of a prior art flash memory device that is connected to a host; and

FIG. 2 is a block diagram of a flash memory device of the present invention, including a self-controlled switch, connected to a host.

### DETAILED DESCRIPTION OF THE PREFERRED EMBODIMENTS

The present invention is a flash memory device including a flash controller and a flash memory for storing information. The flash controller is configured to control power supply to the flash memory, thereby alternately providing and denying power to the flash memory.

As long as the flash controller of the present invention is operationally connected to a host, the flash controller is continuously powered via a power supply (even when not operationally in use by the host) in order to maintain the flash memory device ready for operation on short notice. However, the flash memory is disconnected from power when not in use by the host for a preset time interval, or following an explicit command to that effect sent by the host. When the host requests access to the flash memory following such disconnection, the flash controller provides power to the flash memory and resumes its operation. Such configuration provides optimal power saving. This is in contrast to prior art techniques, in which the flash memory is powered directly from the external power source and is always powered when the controller is powered.

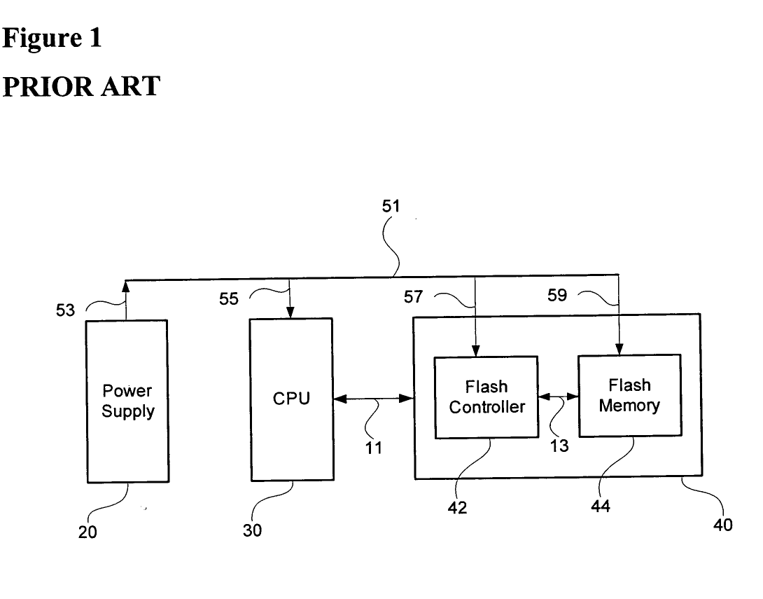

Referring now to FIG. 1, there is shown a block diagram of a prior art flash memory device 40 connected to a host 30 (e.g. CPU). Flash memory device 40 includes a flash controller 42 and a flash memory 44 connected together via a bus 13.

A power supply 20 provides power to CPU 30 via a main power line 51. An output 53 of power supply 20, a power input 55 of CPU 30, a power input 57 of flash controller 42, and a power input 59 of flash memory 44 are all connected to the main power line 51.

Via a bus 11, CPU 30 sends commands to the flash memory device 40 and exchanges data with the flash memory device 40. CPU 30 controls the power supply to both the flash controller 42 and the flash memory 44, such that power is provided/denied to the flash controller 42 through power input 57 and power is provided/denied to the flash memory 44 through power input 59 conditional on commands received from the CPU 30.

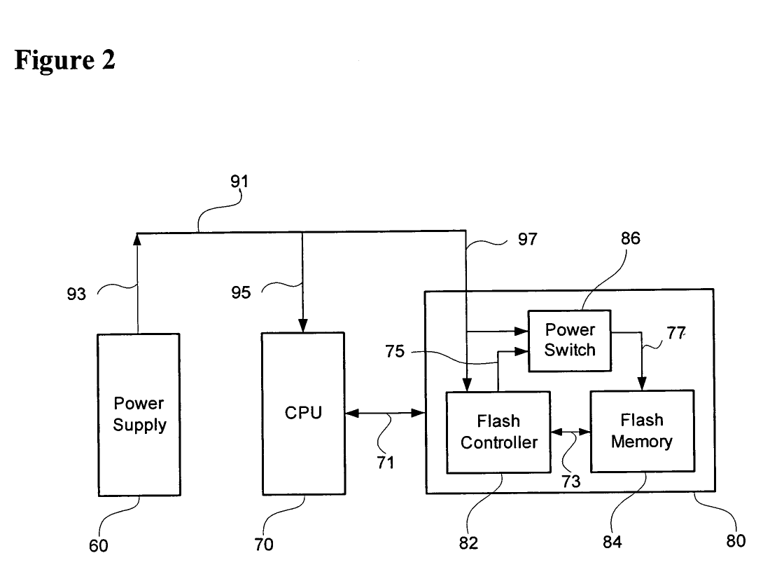

Referring to FIG. 2, there is shown a block diagram of a flash memory device 80 of the present invention connected to a host 70. Flash memory device 80 includes a flash controller 82 and a flash memory 84 connected together via a bus 73.

Flash memory device 80 communicates with a host (e.g. CPU 70) through a bus 71. A power supply 60 provides power to flash memory device 80 and to host 70 via a main power line 91. The output 93 of power supply 60, the power input 95 of host 70 and the power input 97 of flash controller 82 are all connected to the main power line 91.

Via the bus 71, CPU 70 controls the power supply to only the flash controller 82, such that power is provided/denied to the flash controller 82 through power input 97 conditional on commands received from the CPU 70.

Power supply to the flash memory 84 is controlled by the flash controller 82 (and not by the CPU 70). Flash controller 82 controls operation of a power switch 86, via control signals 75. Upon receiving a command from flash controller 82 instructing power switch 86 to initiate or resume providing power to the flash memory 84, power is provided to the flash memory 84 via a power line 77.

The commands issued from the flash controller to initiate or resume supply of power to the memory device may be contingent on values of different parameters, such as the time required for activating the non-volatile memory, the history of use of the non-volatile memory, etc.

Hence, unlike prior art memory techniques, in which power is either enabled or disabled to all sub-units of the a flash memory device, the flash controller of the present invention is configured to alternately provide and deny power to the flash memory component, thus allowing power to be applied to the controller while at the same time power is not applied to the flash memory component.

It should be noted that power switch 86 is implemented in FIG. 2 as an external unit connected to flash controller 82 as an example only. Alternatively, power switch 86 is implemented within flash controller 82.

Having described the invention with regard to certain specific embodiments thereof, it is to be understood that the description is not meant as a limitation, since further modifications will now suggest themselves to those skilled in the art, and it is intended to cover such modifications as fall within the scope of the appended claims.

1. A flash memory device including:
(a) a non-volatile memory for storing information;
(b) a power switch for controlling operation of the memory device; and
(c) a controller that operates said power switch to alternately provide and deny power to said non-volatile memory.

2. The memory device of claim 1, wherein said power switch is implemented within said controller.

3. The memory device of claim 1, wherein said power switch is external to said controller.

4. The memory device of claim 1, wherein said controller alternately provides and denies power to said non-volatile memory in response to commands received from a host.

5. The memory device of claim 1, wherein said controller alternately provides and denies power contingent on a value of time required for activating said non-volatile memory.

6. The memory device of claim 1, wherein said controller alternately provides and denies power contingent on a value of history of use of said non-volatile memory.

7. A method of regulating power consumption of a flash memory device that includes a nonvolatile memory and a controller of the nonvolatile memory, the method comprising the steps of:
(a) supplying power to the controller; and
(b) alternately providing and denying supply of said power, by the controller, to the non-volatile memory.

8. The method of claim 7, wherein said alternately providing and denying is effected in response to commands received from a host of the memory device.

9. The method of claim 7, wherein said alternately providing and denying is contingent on a value of time required for activating the non-volatile memory.

10. The method of claim 7, wherein said alternately providing and denying is contingent on a value of history of use of the non-volatile memory.
